(19) United States
(12) Patent Application Publication
(10) Pub. No.: US 2010/0157647 A1
(43) Pub. Date: Jun. 24, 2010

(54) Memory access circuits and layout of the same for cross-point memory arrays

(75) Inventors: Darrell Rinerson, Cupertino, CA (US); Christophe J. Chevallier, Palo Alto, CA (US); Chang Hua Siau, San Jose, CA (US)

Correspondence Address: UNITY SEMICONDUCTOR CORPORATION, 255 SANTA ANA COURT, SUNNYVALE, CA, 94085-4511, US

(73) Assignee: UNITY SEMICONDUCTOR CORPORATION, SUNNYVALE, CA (US)

(21) Appl. No.: 12/653,898

(22) Filed: Dec. 18, 2009

Related U.S. Application Data
(60) Provisional application No. 61/203,191, filed on Dec. 19, 2008.

(51) Int. Cl. G11C 5/02; H01L 27/00; G11C 8/10

(52) U.S. Cl. 365/51; 257/202; 365/230.06; 257/E27.001

(57) ABSTRACT

An integrated circuit includes a substrate including active circuitry fabricated on the substrate and a cross-point memory array formed above the substrate. The cross-point memory array can include conductive array lines arranged in different directions, and re-writable memory cells. Further, the integrated circuit can also include a memory access circuit configured to perform data operations on the cross-point memory array. The integrated circuit can include a cross-point memory array interface layer positioned between the substrate and the cross-point array and including conductive paths configured to electrically couple portions of the memory access circuit with a subset of the conductive array lines. At least one layer of cross-point memory arrays can be formed over the substrate. The memory cells can be two-terminal memory cells that store data as a plurality of conductivity profiles (e.g., resistive states) that can be non-destructively determined by applying a read voltage across the terminals.

### FIELD OF THE INVENTION

The present invention relates generally to integrated circuits. More specifically, the present invention relates to layout of circuitry for data operations to cross-point memory devices.

### BACKGROUND

Conventional memory support circuits are used to read and write data from an array of memory cells. Examples of memory support circuits include sense amplifiers, row decoders, column decoders, pass gates, drivers, buffers, registers, and the like. Decoder circuits, such as row decoders, can further include row selection circuits and drivers. Semiconductor memories typically require a certain amount of planar area to form memory support circuits, the planar area usually being determined by the quantities and types of devices (as well as device configurations) that are used to form the support circuitry. Further, complementary metal-oxide-semiconductor (“CMOS”) fabrication technologies are commonly used to form the devices of the memory support circuits. CMOS based devices require planar area for both n-channel and p-channel semiconductor structures (e.g., transistors). For CMOS devices, n-wells for the p-channel devices require a lot of area and deep n-wells take up even more area. Therefore, in conventional CMOS based circuitry the use of both p-channel and n-channel devices results in an area penalty created in part by the area required by the n-wells.

Certain approaches to semiconductor memory technologies provide for structures in which memory arrays are formed in multiple levels of memory that are vertically stacked upon a substrate over which the multiple levels of memory have been fabricated. The arrays in each level or layer of memory include memory cells operative to stored data. The substrate (e.g., a silicon wafer) includes active circuitry (e.g., CMOS devices), at least a portion of which is configured as support circuitry for data operations to the multiple levels of memory. In at least one approach, a conventional design arranges some of the memory support circuits, such as row decoders and column decoders, under the multiple levels of memory, with other portions of the memory support circuits being formed without being under the memory levels. In that the portions of the memory support circuits that are not positioned under the multiple levels of memory consume die area and semiconductor resources, which, in turn, contribute to an increase in die size without typically providing for an increase in memory capacity, it is desirable to position as much of the memory support circuitry under as possible under the multiple levels of memory so that the die area is primarily determined by the physical footprint (e.g., a perimeter defined by X and Y dimensions) of the multiple levels of memory. In one proposed approach, a memory architecture arranges row decoders and column decoders in a checkerboard-like arrangement. But there are drawbacks to the various conventional approaches.

One drawback is that in some proposed implementations, each array of multiple levels is formed over only either row decoders or column decoders. Thus, each array structure depends on another array structure for providing memory support circuitry for multiple arrays. A second drawback is that in some proposed implementations, there are row decoders and column decoders that are not formed under memory arrays, tending to increase die size. Further, some proposed implementations of memory support circuitry dispose row selection circuits, row drivers and/or column drivers between arrays rather than underneath, thereby consuming area without typically providing for an increase in memory capacity. Typically, row decoders and column decoders are formed as CMOS-based circuits. A third drawback of proposed memory support circuits is that their structures hinder the formation of relatively smaller-sized memory capacities in which the memory support circuits are disposed underneath an array of multiple levels of memory cells so as to, for example, reduce a die size for the memory.

There are continuing efforts to improve layout, routing, and memory support circuitry for memory devices.

### BRIEF DESCRIPTION OF THE FIGURES

The invention and its various embodiments are more fully appreciated in connection with the following detailed description taken in conjunction with the accompanying drawings, in which:

FIG. 1 depicts an integrated circuit including memory cells disposed in a single layer or in multiple layers of memory, according to various embodiments of the invention;

FIGS. 2A and 2B depicts examples of integrated circuits in which a memory access circuit is disposed under an array of n layers of memory, and is configured to service other arrays, according to at least some embodiments of the invention;

FIGS. 3A and 3B depicts examples of integrated circuits in which portions of a memory access circuit are disposed under different arrays of n-layers of memory, and are configured to service other arrays, according to at least some embodiments of the invention;

FIGS. 4A and 4B depicts examples of X-line decoders and Y-line decoders as memory access circuits with non-contiguous portions, according to at least some embodiments of the invention;

FIGS. 5A through 5D depicts examples of a cross-point memory array interface layer, according to at least some embodiments of the invention;

FIG. 6 depicts examples of structures for conductive paths of a cross-point memory array interface layer and conductive array lines of a memory layer, according to at least some embodiments of the invention;

FIG. 7 is a diagram depicting a cross-section view of an integrated circuit that implements a cross-point memory array interface in association with an array of multiple layers of memory, according to at least some embodiments of the invention;

FIGS. 8A through 8C depict an example of a decoder circuit, according to at least some embodiments of the invention; and

FIG. 9 depicts a decoder including a predecoder and a decoder, according to at least some embodiments of the invention.

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links, for example. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

U.S. patent application Ser. No. 11/095,026, filed Mar. 30, 2005, published as U.S. Pub. No. 2006/0171200, and entitled “Memory Using Mixed Valence Conductive Oxides,” is hereby incorporated by reference in its entirety for all purposes and describes non-volatile third dimensional memory elements that may be arranged in a two-terminal, cross-point memory array. New memory structures are possible with the capability of this third dimensional memory array. In at least some embodiments, a two-terminal memory element or memory cell can be configured to change conductivity when exposed to an appropriate voltage drop across the two-terminals. The memory element can include an electrolytic tunnel barrier and a mixed valence conductive oxide in some embodiments, as well as multiple mixed valence conductive oxide structures in other embodiments. A voltage drop across the memory element can cause an electrical field that is strong enough to move mobile oxygen ions between a mixed valence conductive oxide and an electrolytic tunnel barrier thereby changing a conductivity profile of the memory element, according to some embodiments.

In some embodiments, an electrolytic tunnel barrier and one or more mixed valence conductive oxide structures do not need to operate in a silicon substrate, and, therefore, can be fabricated above circuitry being used for other purposes. For example, a substrate (e.g., a silicon-Si wafer) can include active circuitry (e.g., CMOS circuitry) fabricated on the substrate as part of a front-end-of-the-line (FEOL) process. After the FEOL process is completed, one or more layers of two-terminal cross-point memory arrays are fabricated over the active circuitry on the substrate as part of a back-end-of-the-line process (BEOL). The BEOL process includes fabricating the conductive array lines and the memory cells that are positioned at cross-points of conductive array lines (e.g., row and column conductive array lines). An interconnect structure (e.g., vias, thrus, plugs, damascene structures, and the like) may be used to electrically couple the active circuitry with the one or more layers of cross-point arrays. Further, a two-terminal memory element can be arranged as a cross-point such that one terminal is electrically coupled with an X-direction line (or an “X-line”) and the other terminal is electrically coupled with a Y-direction line (or a “Y-line”). A third dimensional memory can include multiple memory elements vertically stacked upon one another, sometimes sharing X-direction and Y-direction lines in a layer of memory, and sometimes having isolated lines. When a first write voltage, VW1, is applied across the memory element (e.g., by applying ½ VW1 to the X-direction line and ½ −VW1 to the Y-direction line), the memory element can switch to a low resistive state. When a second write voltage, VW2, is applied across the memory element (e.g., by applying ½ VW2 to the X-direction line and ½ −VW2 to the Y-direction line), the memory element can switch to a high resistive state. Memory elements using electrolytic tunnel barriers and mixed valence conductive oxides can have VW1 opposite in polarity from VW2.

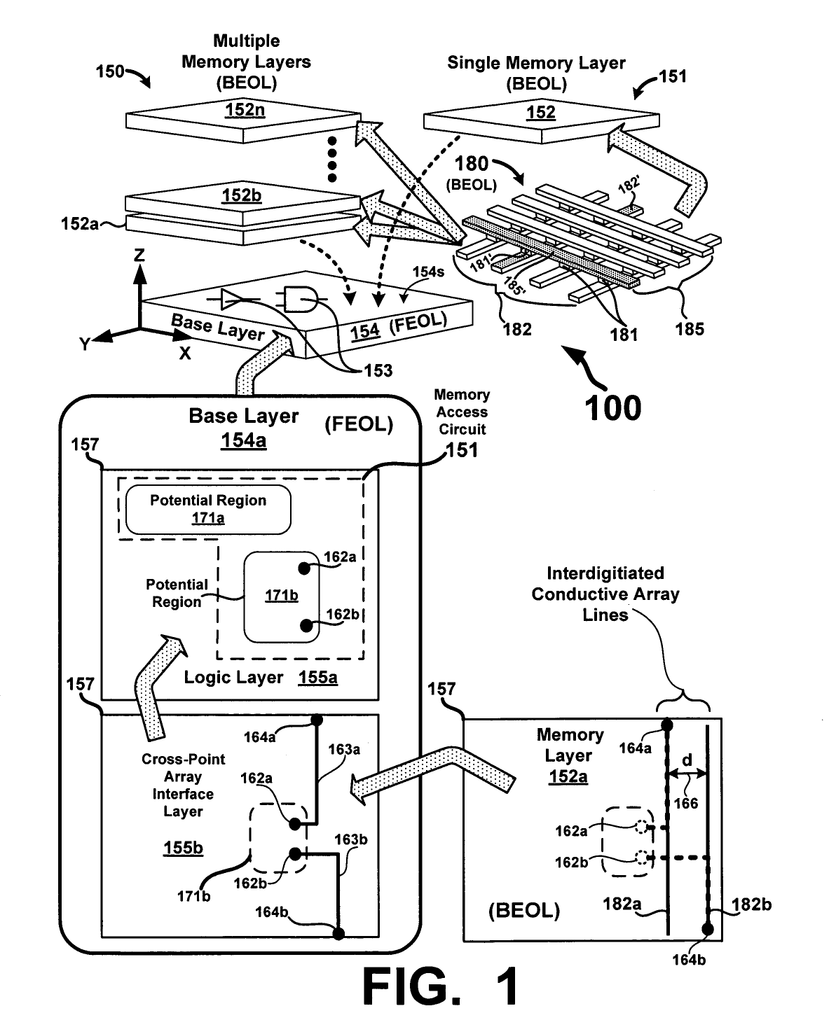

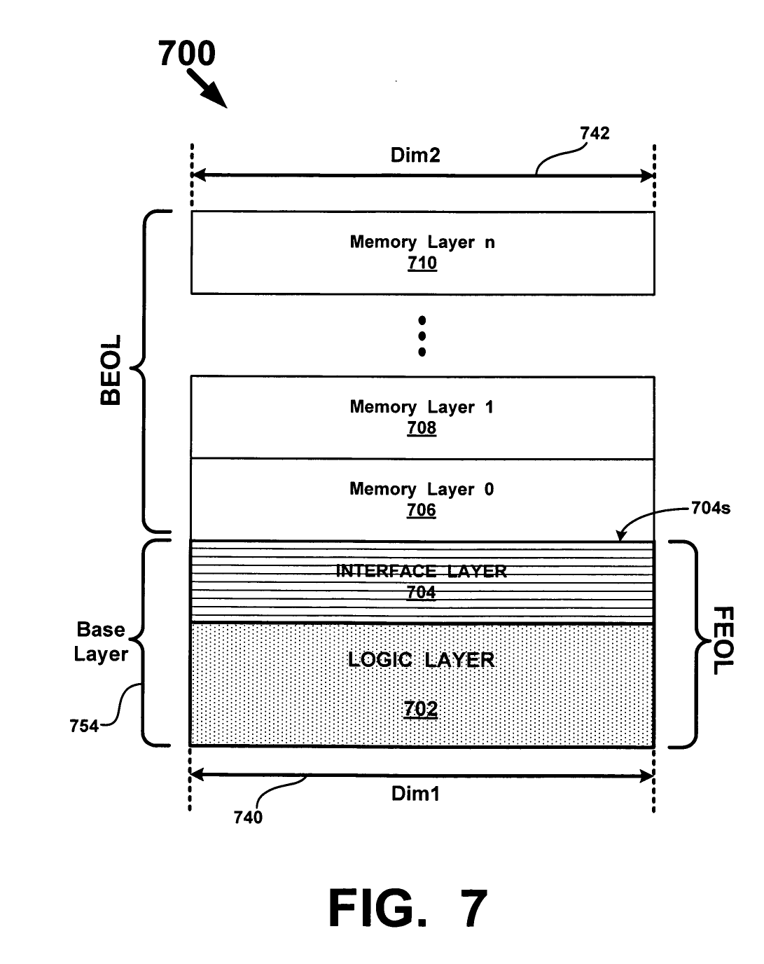

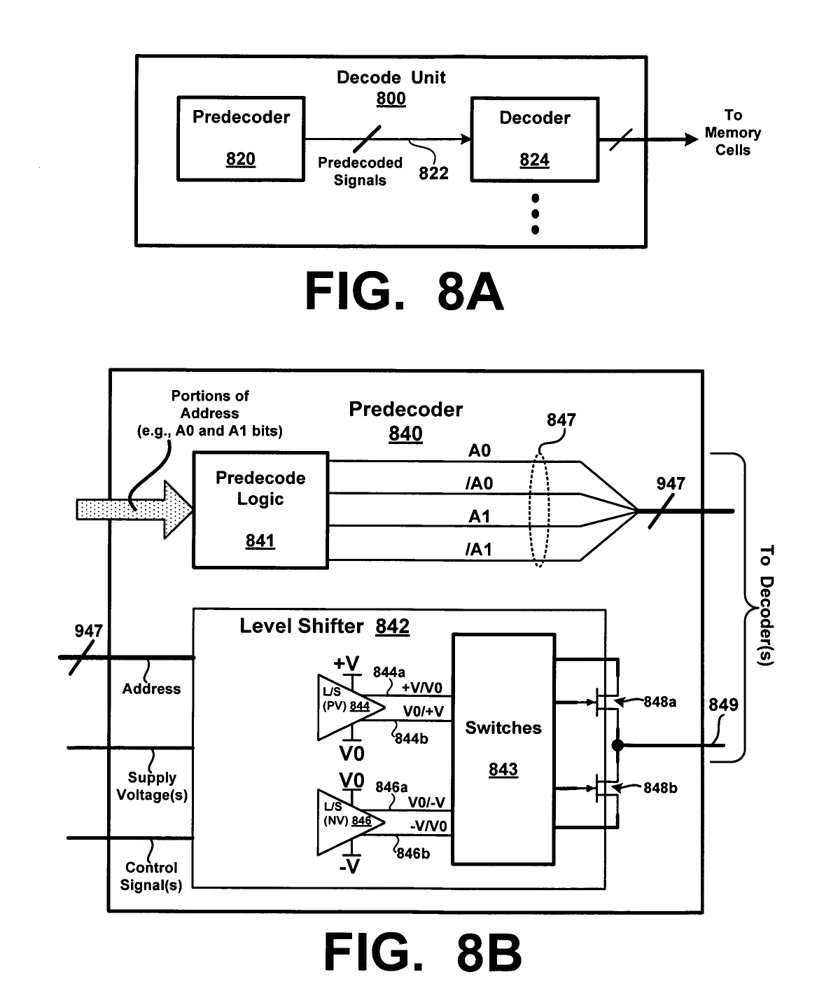

FIG. 1 illustrates an integrated circuit 100 including memory cells disposed in a single layer or in multiple layers of memory, according to various embodiments of the invention. In this example, integrated circuit 100 is shown to include either multiple layers 150 of BEOL memory or a single layer 151 of BEOL memory in contact with a surface 154s and vertically fabricated directly above a FEOL base layer 154. In at least some embodiments, each layer 152 or 152a-152n of memory can include a BEOL cross-point array 180 including conductive array lines 182 and 185 arranged in different directions (e.g., substantially orthogonal to one another) to access memory cells, such as two-terminal memory cells 181, for example. Each memory cell 181 is positioned substantially between a cross-point of a single conductive array line 182 (e.g., a column conductor or Y-direction array line) with another conductive array line 185 (e.g., a row conductor or X-direction array line), such that one terminal of the memory cell 181 is electrically coupled with only one of the array lines 182 and the other terminal of the memory cell 181 is electrically coupled with only one of the array lines 185. The coupling of the terminals of the memory cell 181 with its respective array lines (182, 185) places the memory cell 181 electrically in series with the array lines (182, 185). Data operations (e.g., read or write operations) the memory cells 181 are accomplished by applying a read or write voltage across the respective array lines (182, 185) as depicted by selected memory cell 181′ and conductive array lines 182′ and 185′ across which a select voltage (e.g., a read or write voltage) is applied by active circuitry 153 in base layer 154. Base layer 154 can include a bulk semiconductor substrate (e.g., a silicon wafer) upon which memory access circuits can be formed. Optionally, other circuits can be formed on the base layer 154 and those circuits can be configured to perform functions that are unrelated to data operations on the memory arrays. The logic layer 155a can be considered a product of front-end-of-the-line (FEOL) processing and cross-point array interface layer 155b is roughly equivalent to the metallization layers produced by “conventional” back-end-of-the-line (conventional BEOL) processing. Here, logic layer 155a and cross-point array interface layer 155b are regarded as FEOL structures in base layer 154a because the one or more layers of memory will be subsequently fabricated BEOL directly on top of the cross-point array interface layer 155b. Hereinafter, the term BEOL will refer BEOL memory layers (e.g., all memory structure above uppermost surfaces 154s in FIGS. 1 and 704s in FIG. 7) and the term FEOL will refer to all the structure positioned below the BEOL memory layers (e.g., FEOL base layer 154a which includes the logic layer 155a and interface layer 155b). Further, cross-point array interface layer 155b can be formed under one memory layer (e.g., 152) or under multiple memory layers (e.g., 152a-152n). Logic layer 155a can be a layer that includes circuitry that can be configured to perform a variety of functions, including functions for accessing memory layer 152a to write or read data. For example, a memory access circuit 151 can be formed in logic layer 155a to include either a single potential region (not shown) or multiple potential regions, such as potential regions 171a and 171b. Examples of memory access circuits 151 include but are not limited to predecoders, decoders, and sense amplifiers, just to name a few. In some instances, potential regions 171a and 171b can be formed to constitute non-contiguous portions of memory access circuit 151. Cross-point array interface layer 155b can be configured to provide electrical connectivity between a portion of memory access circuit 151, such as potential region 171b, and conductive array lines 182a and 182b formed in memory layer 152a. For example, a portion of memory access circuit 151 can include connection points (e.g. vias) 162a and 162b, which, in turn, are coupled to conductive paths 163a and 163b, respectively, of cross-point array interface layer 155b. Conductive paths 163a and 163b are coupled to connection points (e.g., vias) 164a and 164b, respectively, which, in turn, are coupled to conductive array lines 182a and 182b. In at least some embodiments, conductive array lines 182a and 182b are interdigitated or interleaved at a distance (“d”) 166 from each other. In other embodiments, conductive array lines are interdigitated in groups (e.g., 2 lines driven from one side are adjacent and two lines driven from the other side are next to them). In either case the term “interdigitated” can be used. In at least some embodiments, conductive paths 163a and 163b of cross-point array interface layer 155b, and potential regions 171a and 171b of memory access circuit 151 can be formed entirely under either the multiple layers 150 of memory (e.g., between logic layer 155a and bottommost array layer 152a) or the single layer 151 of memory (e.g., between logic layer 155a and single array layer 152).

In view of the foregoing, the structures of integrated circuit 100 can facilitate a reduction in memory area by reducing the size of the layers 152 of memory, at least in the X and Y dimensions, while forming memory access circuit 151 and other similar circuits underneath the layers 152 of memory so as to conserve semiconductor material, and to minimize area consumed by memory access circuit 151 that might otherwise increase die size, according to some embodiments. By forming memory access circuit 151 as non-contiguous portions, at least one portion, such as the portion associated with potential region 171b, can be “folded” into, or otherwise disposed within a periphery 157 of integrated circuit 100. Periphery 157 can describe a boundary that demarcates an area in a plane in the X and Y dimensions over which memory layers 152a-152n or memory layer 152 are formed, according to some embodiments. In some examples, memory access circuit 151 can be a column decoder that is distributed as portions within periphery 157, for example, to avoid spatial conflicts with layouts of other decoders (e.g., a row decoder). Accordingly, the circuitry and interconnect structures in the logic layer 155a and the cross-point array interface layer 155b are positioned within the boundaries defined by periphery 157.

Further, cross-point array interface layer 155b can be configured to arrange conductive array lines 182a and 182b in a direction that is the same (or is substantially the same) as the conductive array lines associated with another portion, thereby facilitating formation of sets of conductive array lines, such as X-lines and Y-lines, of a cross-point array, according to various embodiments. In some embodiments, the conductive array lines, such as conductive array lines 182a and 182b, can be interdigitated to space apart the conductive array lines from one another other by an appropriate pitch, while facilitating relatively larger driver sizes at the logic layer 155a or connection points (e.g., vias) 164a and 164b (e.g., as compared to the pitch of conductive array lines 182a and 182b). In various embodiments, logic layer 155a can be formed using CMOS, NMOS, or PMOS fabrication technology or any other known semiconductor technology

In at least some embodiments, potential regions 171a and 171b can be formed in the substrate using a common material. For example, potential regions 171a and 171b can be formed from the material of the bulk substrate (e.g., a silicon substrate including appropriate dopants, such as the dopants necessary to produce a p-type bulk), or they can be formed from a semiconductor material and/or structure, such as a p-type well or n-type well (also referred to as a tub) depending on the doping type of the bulk substrate the well are formed in. According to some embodiments, these potential regions 171a and 171b can thus provide for the fabrication of homogenous transistors, such as only NMOS devices or only PMOS devices. As one example, homogenous NMOS transistors can be formed in a p-type semiconductor substrate (e.g., silicon wafer). As a second example, homogenous PMOS transistors can be formed in a n-well region that is formed in a p-type semiconductor substrate (e.g., silicon wafer). One advantage to using homogenous transistors to implement circuitry is that the space between transistors can be reduced with an associated reduction an area used when the transistors are all of the same type (e.g., all p-type or all n-type). Since memory access circuit 151 can be fabricated to include homogeneous transistors, the feature size of such circuits can be reduced in comparison to CMOS devices that require additional area to form, for example, an n-well for a PMOS portion of a CMOS device. In various embodiments, memory access circuit 151 can compose entirely of homogenous transistors, predominately of homogenous transistors, or a majority of homogenous transistors. By reducing the feature sizes collectively, the sizes of memory access circuits 151, such as decoders, drivers, sense amplifiers and the like, can be reduced, thereby reducing the area encompassed by periphery 157. As used herein, the term “potential regions” can refer, at least in some embodiments, to a region in which similar semiconductor materials, which can include either p-doped or n-doped materials, are disposed to form homogenous transistors (e.g., NMOS only devices) in that region (or a substantial portion thereof). As used herein, the term “homogenous” can refer, at least in some embodiments, to transistors that have a common attribute relating to the semiconductor materials used in their fabrication, such as material used to form the channel. Thus, the term “homogenous” need not require the sizes, functions, or any other attribute of the transistors to be the same.

### Sharing Circuit Elements Across Arrays

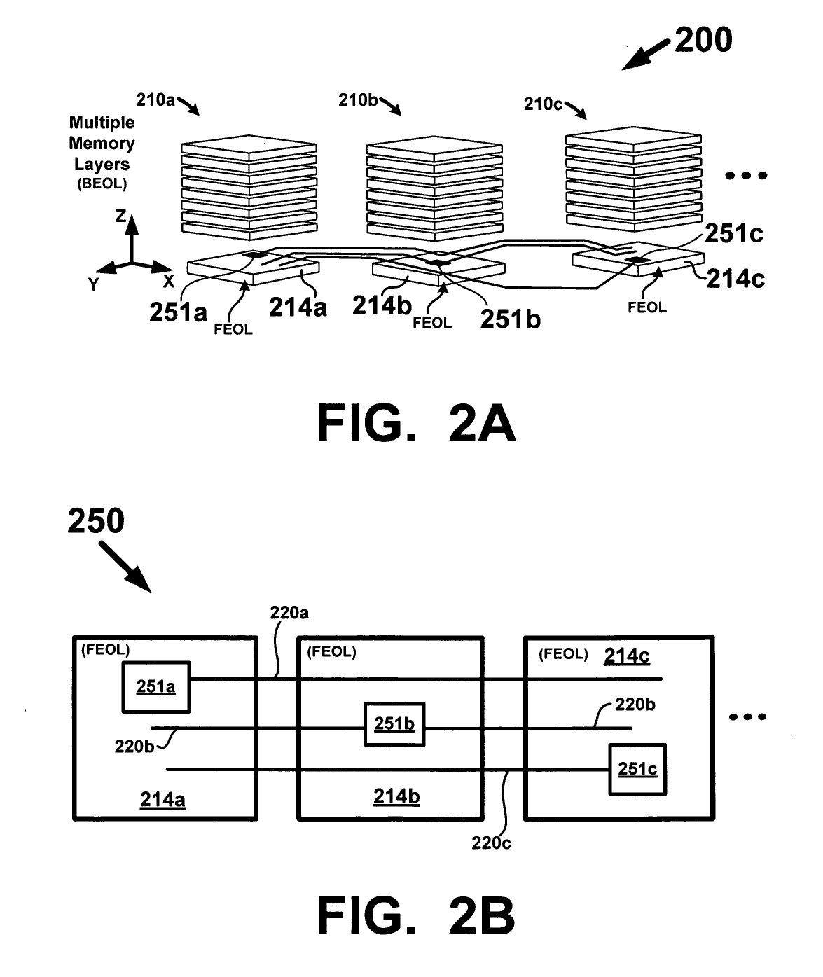

FIGS. 2A and 2B depict examples of integrated circuits in which memory access circuits are disposed under a memory array comprising one or more layers of memory, and configured to service other arrays positioned over the same base layer (e.g., base layer 154 of FIG. 1), according to at least some embodiments of the invention. Configuration 200 of FIG. 2A depicts multiple vertically stacked arrays 210a, 210b, and 210c of memory formed respectively on portions of the same base layer denoted as portions 214a, 214b, and 214c. Memory access circuits 251a, 251b, and 251c (e.g., comprising NMOS or PMOS devices) are respectively formed in their respective portions 214a, 214b, and 214c, each of which can be part of a common, monolithic substrate (e.g., a single silicon-Si wafer or a die cut from the silicon wafer). Although configuration 200 depicts multiple layers of vertically stacked memory, a single layer of memory can be formed over the access circuits 251a, 251b, and 251c for portions 214a, 214b, and 214c, respectively. Additionally, the base layer portions 214a, 214b, and 214c and their associated vertically stacked arrays 210a, 210b, and 210c can be spread out across the base layer 154 (as depicted in the FIGs) or adjacent to each other, depending on the architectural requirements.

FIG. 2B is a top view 250 depicting memory access circuits 251a, 251b, and 251c of the configuration 200 of FIG. 2A that are respectively formed on portions 214a, 214b, and 214c. In at least some embodiments, each of the memory access circuits 251a, 251b, and 251c can be configured to provide the same or different functions relating to data operations on memory (e.g., reading or writing data). As such, each of memory access circuits 251a, 251b, and 251c can individually be configured to provide a memory access function to interact via one or more conductive paths 220a, 220b, and 220c with arrays 210a, 210b, and 210c, respectively. For example, memory access circuits 251a, 251b, and 251c can each be configured to operate as row decoders that provide row decoding functionality to access the multiple layers in arrays 210a, 210b, and 210c. As another example, memory access circuits 251a, 251b, and 251c can each be sense amplifier circuits that provide sensing functionality to access the multiple layers in arrays 210a, 210b, and 210c to sense values of read data (e.g., logic “0” or logic “1”). In at least some embodiments, memory access circuits 251a, 251b, and 251c can be composed of homogenous transistors, such as only NMOS transistors or only PMOS transistors, for example.

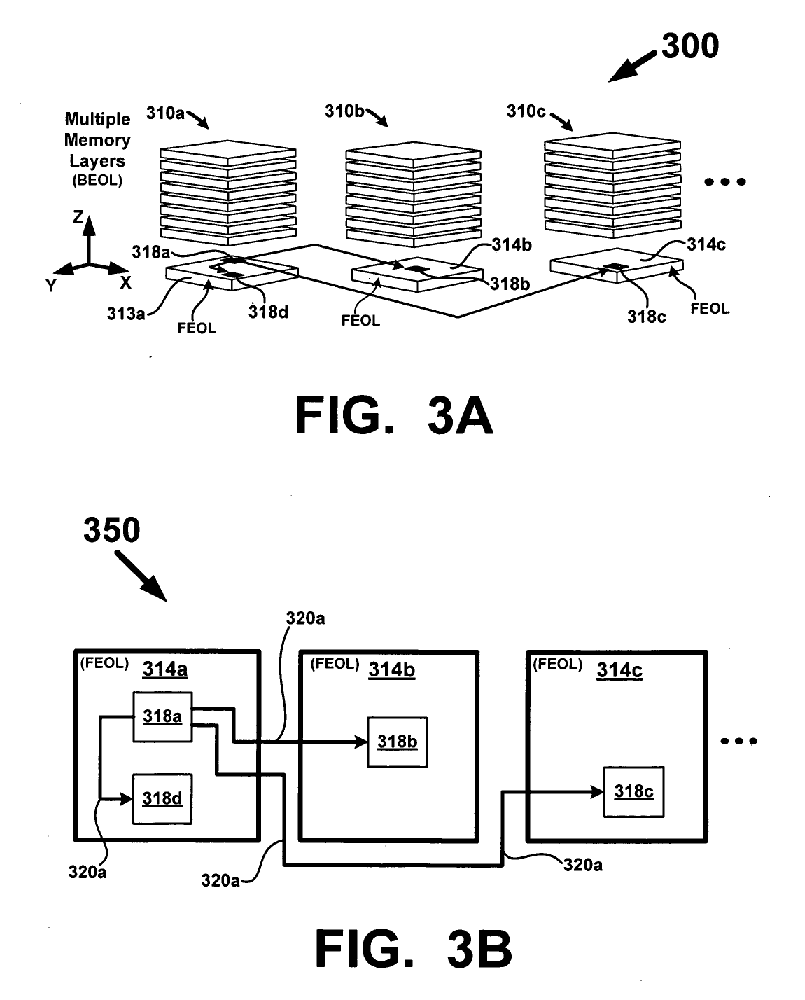

FIGS. 3A and 3B depict examples of integrated circuits in which portions of a memory access circuit are disposed under different arrays of one or more layers of memory, and are configured to service other arrays positioned over the same base layer (e.g., base layer 154 of FIG. 1), according to at least some embodiments of the invention. Configuration 300 of FIG. 3A shows arrays 310a, 310b, and 310c of multiple layers of memory formed respectively on the same base layer and denoted as portions 314a, 314b, and 314c. In this example, memory access circuits 318a and 318d are formed on portion 314a, whereas memory access circuits 318b and 318c are respectively formed on portions 314b and 314c. Portions 314a, 314b, and 314c can be part of a common, monolithic substrate (e.g., a silicon wafer or a die cut therefrom).

FIG. 3B is a top view 350 depicting memory access circuits 318a, 318b, 318c and 318d of configuration 300 in FIG. 3A that are formed on portions 314a, 314b, and 314c. In at least some embodiments, one or more of memory access circuits 318a, 318b, 318c and 318d can be configured to provide the same or different functions relating to data operations, such as reading and writing data, for example. As such, each of memory access circuits 318a, 318b, 318c and 318d can individually be configured to provide one or more different portions of a memory access function to interact with one or more of the arrays 310a, 310b, and 310c. For example, memory access circuits 318a, 318b, 318c and 318d can be configured as portions of a decoder that collectively operate to provide decoding functionality to access any of arrays 310a, 310b, and 310c. In particular, memory access circuit 318a can be formed as a predecoder circuit and memory access circuits 318b, 318c and 318d can be formed as postdecoder circuits (e.g., final decoder circuits), whereby predecoder 318a can be configured to generate predecoded signals that can be transmitted via conductive paths 320a to postdecoder circuits 318b, 318c and 318d, any of which can complete the decoding process to access a corresponding array 310a, 310b, and 310c of memory. Thus, a predecoder formed under one array can be configured to cooperate with a decoder formed under another array. In at least some embodiments, memory access circuits 318a, 318b, 318c and 318d can be composed of homogenous transistors, such as only NMOS transistors or only PMOS transistors, for example. In at least some embodiments, memory access circuit 318a can be a first decoder portion and memory access circuit 318b can be a second decoder portion, both of which can be configured to cooperate to select, for example, interdigitated conductive array lines to access re-writable memory cells.

### Folding Decoders Underneath an Array

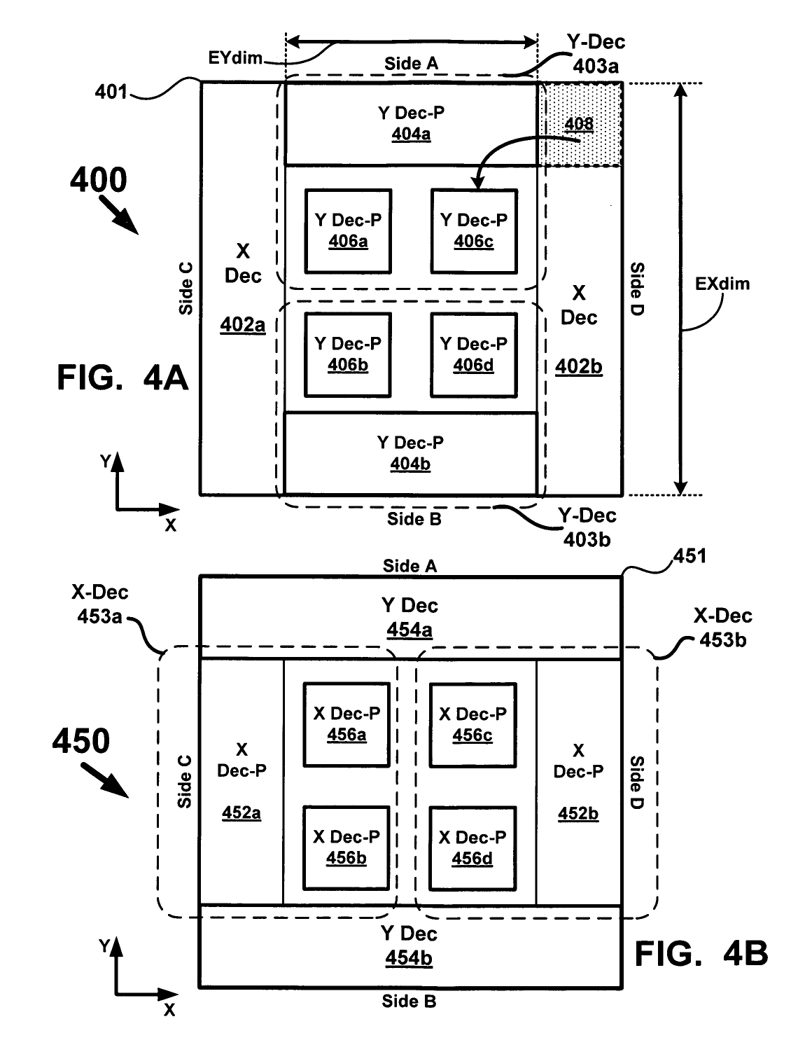

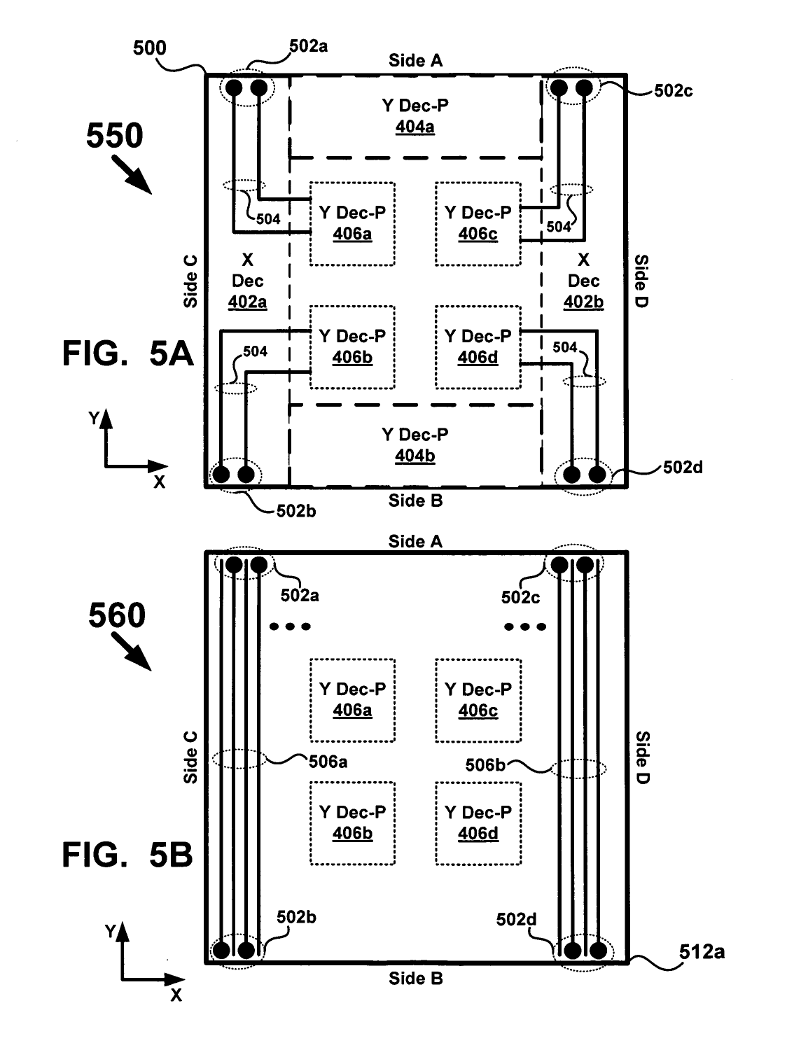

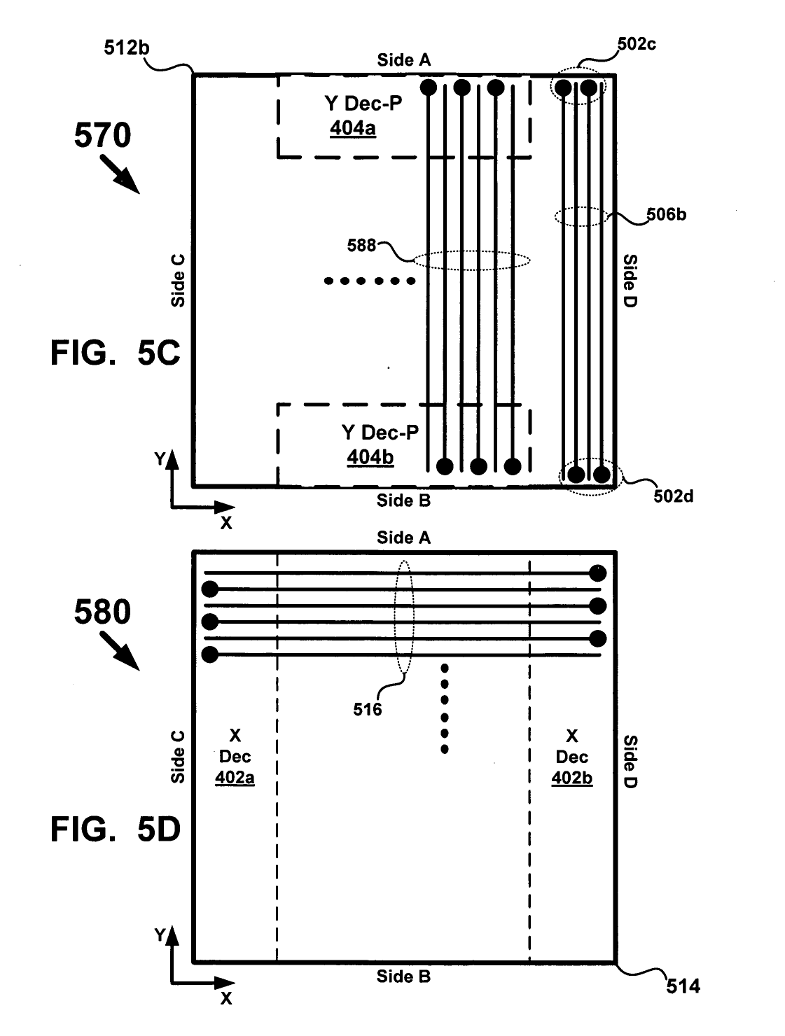

FIGS. 4A and 4B depict examples of X-line decoders and Y-line decoders as memory access circuits including non-contiguous portions, according to at least some embodiments of the invention. Configuration 400 of FIG. 4A is a top view of a base layer including X decoders (“X Dec”) 402a and 402b and Y decoders (“Y Dec”) 403a and 403b (shown in dashed line) including non-contiguous portions (“Y Dec-P”), denoted as Y decoder portions 404a and 404b, as well as Y decoder portions 406a, 406b, 406c, and 406d. In at least some embodiments, all of the foregoing circuits can be formed in a base layer within a periphery 401, which demarcates the boundary of an array in the X and Y dimensions. In this example, X decoders (“X Dec”) 402a and 402b are positioned at opposite sides of the base layer along sides C and D of the base layer, and arranged so that the elongated dimension, EXdim, extends from side A to side B. This arrangement facilitates interdigitating the X-line conductive array lines, such as depicted in FIG. 5D, that originate from X decoders 402a and 402b at any location from side A to side B.

Y decoders 403a and 403b include respective non-contiguous Y decoder portions 404a and 404b, which are positioned at opposite sides of the base layer along sides A and B, and are arranged so that the elongated dimension, EYdim, extends from locations adjacent X decoder 402a to locations adjacent X decoder 402b. This arrangement facilitates interdigitating the Y-line conductive array lines, such as a portion 588 of the Y-line conductive array lines shown in FIG. 5C that originate from locations within Y decoder portions 404a and 404b. Also, Y decoder 403a includes non-contiguous Y decoder portions 406a and 406c, and Y decoder 403b also includes non-contiguous Y decoder portions 406b and 406d. Y decoder portions 406a, 406b, 406c, and 406d are formed as non-contiguous portions so as to reduce spatial conflicts with the X decoders 402a and 402b, which, in turn, assists in keeping the X and Y dimensions of the base layer in some embodiments equal to (or less than in other embodiments) that of periphery 401 of the memory array (not shown) formed upon the base layer. Y decoder portions 406a, 406b, 406c, and 406d can be described as portions of the Y decoders 403a and 403b that are “folded into” the central portion of the base layer. For example, Y decoder portion 406c is a non-contiguous portion of Y decoder 403a that otherwise might have been located at a region 408, which would otherwise be a region of spatial conflict with X decoder 402b. That is, if not located further within the periphery 401, the presence of Y decoder 403a in the region 408 could present an obstacle to routing and/or interdigitating conductive lines to X decoder 402b as will be described below.

Configuration 450 of FIG. 4B depicts a top view of a base layer including Y decoders (“Y Dec”) 454a and 454b and X decoders (“X Dec”) 453a and 453b having non-contiguous portions (“X Dec-P”), such as X decoder portions 452a and 452b, and as X decoder portions 456a, 456b, 456c, and 456d. In this example, Y decoders (“Y Dec”) 454a and 454b are positioned at opposite sides of the base layer along sides A and B and arranged so that their elongated dimensions extend from side C to side D. This arrangement facilitates interdigitating the Y-line conductive array lines in a manner similar to that of the interdigitated X-line conductive array lines 516 depicted in FIG. 5D, with the exception that the Y-line conductive array lines are typically orthogonal to the X-line conductive array lines and would be routed between sides A and B of the base layer and substantially parallel with sides C and D of the base layer. In at least some embodiments, all of the foregoing circuits can be formed in a base layer within a periphery 451, which demarcates the boundary of a memory array in the X and Y dimensions. In this example, portions of X decoders 453a and 453b of FIG. 4B are configured to have similar structures and/or functions as Y decoders 403a and 403b of FIG. 4A, and X decoder portions 456a, 456b, 456c, and 456d of FIG. 4B can be configured to have similar structures and/or functions as Y decoder portions 406a, 406b, 406c, and 406d of FIG. 4A. In at least some embodiments, the X decoders and Y decoders of FIGS. 4A and 4B can include decoder circuits (e.g., predecoder circuits and subsequent decoding circuits), driver circuits, row select circuits and the like. In at least some embodiments, sense amplifiers can replace at least one set of the decoders shown in FIGS. 4A and 4B. In at least some embodiments, the X and Y decoders illustrated in FIGS. 4A and 4B can include any number of decoder portions, regardless of whether they are non-contiguous.

FIGS. 5A through 5D depict examples of a cross-point memory array interface layer, according to at least some embodiments of the invention. FIG. 5A depicts a top view of a cross-point memory array interface layer 550 formed within, for example, of a periphery 500 having the X and Y dimensions of a memory array (not shown) that is fabricated above the cross-point memory array interface layer 550. In this example, the cross-point memory array interface layer 550 can be formed upon a base layer including X decoders 402a and 402b and Y decoder portions 404a, 404b, 406a, 406b, 406c, and 406d. Each of the decoders and decoder portions are shown in dashed lines to represent being formed (e.g., previously fabricated) under the cross-point memory array interface layer 550. In at least some embodiments, the cross-point memory array interface layer 550 can include groups of electrically conductive paths 504 between Y decoder portions 406a, 406b, 406c, and 406d and electrically conductive connection points 502a, 502b, 502c, and 502d, respectively. Examples of a connection point include but are not limited to a terminal, a contact, a via, a plug, a damascene structure, and the like. Examples of electrically conductive paths 504 include but are not limited to a layer of metal fabricated on the interface layer 550, such as metal 3 (m3) or metal 4 (m4).

FIG. 5B depicts groups of interdigitated conductive array lines formed above groups of conductive paths of the cross-point memory array interface layer 560, according to one embodiment. Further, FIG. 5B depicts that group 506a and group 506b of Y-line conductive array lines of memory layer n, which are shown as interdigitated conductive array lines, can be formed above groups 504 of conductive paths shown in FIG. 5A. For example, groups 504 can be fabricated in a layer of metal (e.g., m3) and groups 506a and 506b can be formed in another layer of metal (e.g., m4) as part of a semiconductor fabrication process. Groups 506a and 506b of Y-line conductive array lines will be on the same layer of metal as other Y-line conductive array lines for the memory layer n (e.g., group 588 of FIG. 5C). In addition, groups 506a and 506b can be formed within periphery 512a of a memory array (not shown). As an example, consider that group 506a of interdigitated conductive array lines can be coupled via connection points 502a and 502b to Y decoder portions 406a and 406b, respectively; whereas, group 506b of interdigitated conductive array lines can be coupled via connection points 502c and 502d to Y decoder portions 406c and 406d. Generally, connection points 502a to 502d can be vias that are configured to electrically couple groups 504 of conductive paths (associated with Y decoder portions 406a to 406d) to either group 506a or group 506b of interdigitated conductive array lines in FIG. 5B. In some embodiments, connections points 502a to 502d can be positioned above a portion of the substrate that excludes Y decoder portions 406a, 406b, 406c and 406d, such as over other circuitry. Collectively, FIGS. 5A and 5B depict that at least one conductive path in groups 504 in cross-point memory array interface layer 550 can include a portion that is orthogonal to either group 506a or group 506b of interdigitated conductive array lines in cross-point memory array interface layer 560 of FIG. 5B. Thus, either group 506a or group 506b of interdigitated conductive array lines can be arranged over the X decoders 402a and 402b.

FIG. 5C depicts a group of interdigitated conductive array lines formed adjacent to another group of interdigitated conductive array lines that are associated with a different decoder portion, according to at least some embodiments of the invention. A cross-point memory array interface layer 570 in FIG. 5C illustrates that other portions of a Y decoder can include Y decoders (“Y Dec-P”) 404a and 404b within periphery 512b of a memory array (not shown). In this example, Y decoders 404a and 404b are elongated in a direction that is orthogonal (or substantially orthogonal) to a group 506b of conductive array lines, which can be each arranged in the same direction. Further, conductive paths in the cross-point memory array interface layer 570 can be configured to arrange group 506b of conductive array lines in a formation that is substantially parallel to a group 588 of conductive array lines, which pass over and/or originate from either Y decoders 404a or 404b. Groups 506b and 588 of conductive array lines therefore can constitute the Y-lines (e.g., column lines) for a cross-point array. As shown, group 506b of conductive array lines are indirectly coupled via cross-point memory array interface layer 570 to a decoder, whereas group 588 of conductive array lines are directly coupled (including vias) to a decoder.

Configuration 580 in FIG. 5D depicts a group 516 of interdigitated conductive array lines associated with X decoders 402a and 402b, which individually are contiguous. Group 516 of interdigitated conductive array lines are formed under a memory array (not shown) and within periphery 514 of the array. In this example, the interdigitated conductive array lines in group 516 are vertically coupled (including vias and metal plugs) to X decoders 402a and 402b and need not implement the conductive pathway structures of a cross-point memory array interface layer, such as the layers 570, 560, and 550, described above.

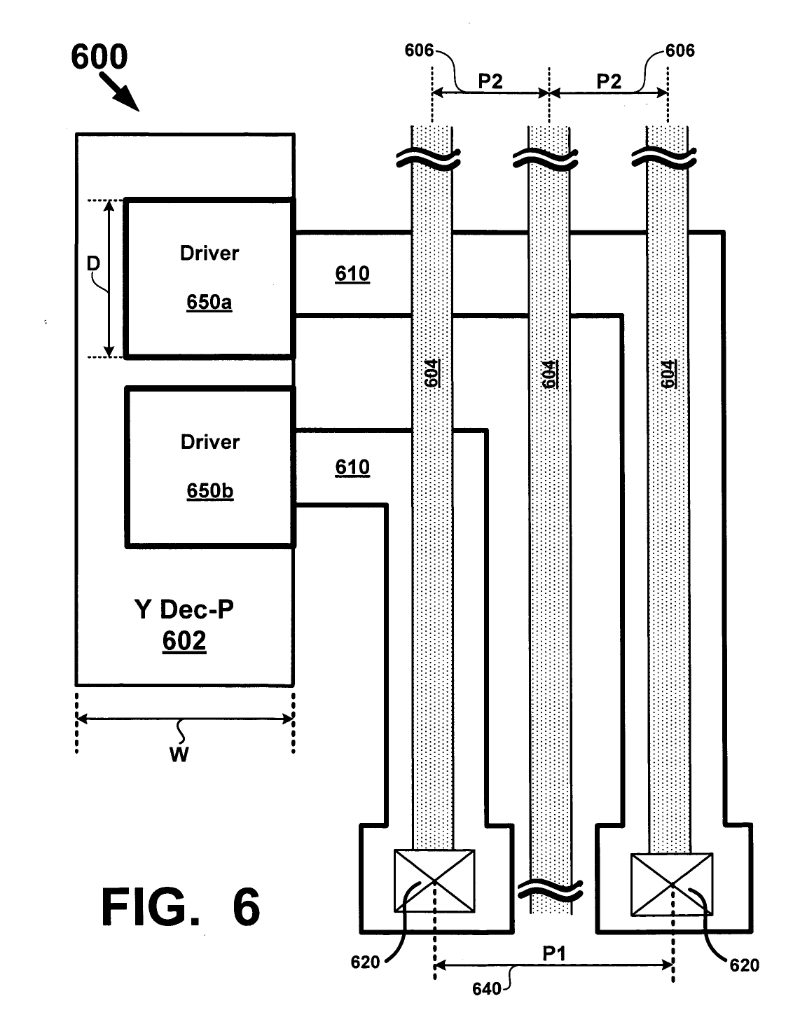

FIG. 6 depicts examples of structures for conductive paths of a cross-point memory array interface layer and conductive array lines of a memory layer, according to at least some embodiments of the invention. Configuration 600 depicts a Y decoder portion (“Y Dec-P”) 602 including drivers 650a and 650b, which, in turn, are configured to drive memory access signals (e.g., voltage signals) onto respective conductive paths 610. Vias 620 are configured to electrically couple conductive paths 610 to conductive array lines 604, which are shown to be interdigitated. In at least some embodiments, conductive paths 610 are formed using a first fabrication technology (e.g., a FEOL process) that determines a pitch (“P1”) 640 between conductive paths 610, whereas conductive array lines 604 are formed using a second fabrication technology (e.g., a BEOL process) that determines a pitch (“P2”) 606. In at least some embodiments, conductive array lines 604 have pitches (e.g., center-to-center conductor distances, also called a “minimum feature size”) that are less than pitches of conductive paths 610 of the cross-point memory array interface layer. As an example, consider that pitch 640 can be associated with a 90 nm fabrication technology and pitch 606 can be associated with a 45 nm fabrication technology. In this manner an aggressive memory densities could be achieved with a cutting-edge P2 while a lower cost fabrication technology P1 could be used for the underlying circuitry. Drivers 650a and 650b can be formed side-by-side so as to maintain a width, W, of Y decoder portion 602 to conserve area of the decoder 602, rather than staggering drivers 650a and 650b in a manner that might otherwise increase the width, W, of Y decoder portion 602. In some examples, Y decoder portion 602 can be a non-contiguous portion.

FIG. 7 is a diagram depicting a cross-section view of an integrated circuit that implements a cross-point memory array interface in association with an array of multiple layers of BEOL memory, according to at least some embodiments of the invention. Here, integrated circuit 700 can be formed to include multiple memory layers 706 to 710 and a FEOL base layer 754, which can include a cross-point memory array interface layer 704 and a logic layer 702. As shown, cross-point memory array interface layer 704 and logic layer 702 have a dimension (“Dim 1”) 740 that can coincide with a dimension (“Dim 2”) 742 for an array including memory layers 706 to 710. Examples of memory layers 706 to 710 include one or more cross-point memory arrays. Thus, cross-point memory array interface layer 704 and logic layer 702 can be formed entirely under an array composed of multiple memory layers 706 to 710, or a single memory layer (e.g., only the layer 706). For example, as part of a front-end-of-the-line (FEOL) fabrication process, circuitry can be fabricated on a substrate (e.g., a silicon wafer) to form the logic layer 702 followed by additional fabrication steps to from the various dielectric and electrically conductive structures for the interface layer 704. As was described above, at least some of the circuitry in logic layer 702 can be implemented using homogenous devices, such as only NMOS transistors or only PMOS transistors, for example. A surface 704s of an upper most layer of the interface layer 704 can be planarized (e.g., using CMP) and include plugs, vias, or the like. Subsequently, as part of a back-end-of-the-line (BEOL) fabrication process, the dielectric, electrically conductive (e.g., array lines and electrodes), and active structures (e.g., CMO based memory cells) can be formed on top of and in contact with the surface 704s of the upper most layer of the interface layer 704 to form the one or more layers of memory (e.g., layers 706 through 710) with the electrically conductive structures in the interface layer 704 electrically coupling the memory layers with the circuitry in the logic layer 702.

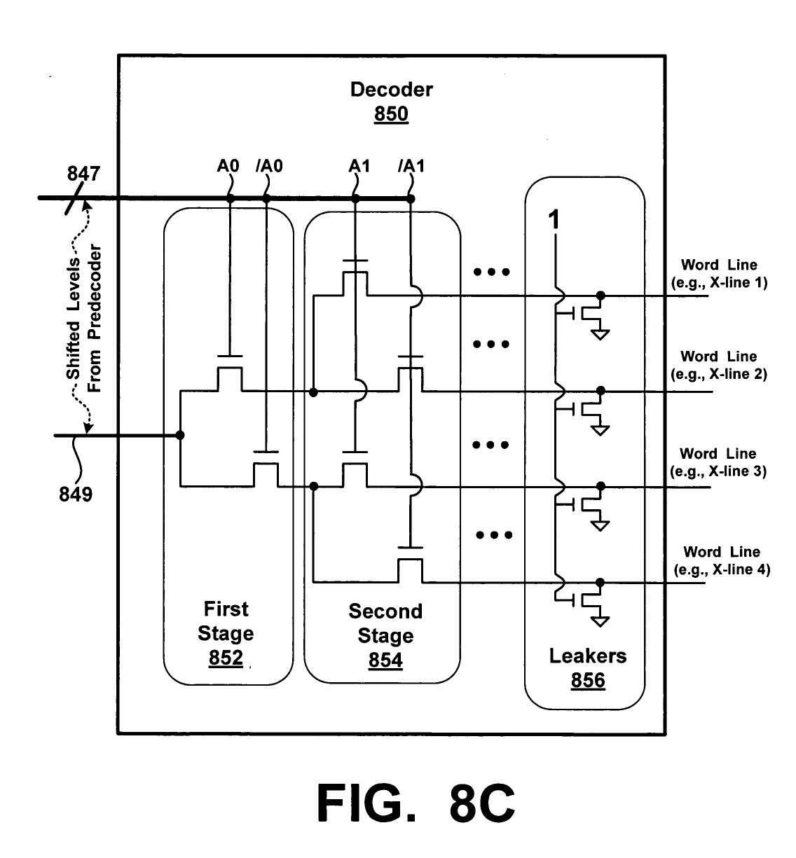

FIGS. 8A to 8C illustrate an example of a decoder circuit, according to at least some embodiments of the invention. FIG. 8A depicts a decode unit 800 including a predecoder 820 and a decoder 824. Predecoder 820 is configured to generate predecoded signals that are communicated via path 822 to decoder 824, or to any number of additional decoders 824 (not shown). Thus, predecoder 820 can be configured to decode a portion of an address (e.g., a group of address bits) and to generate a predecoded signal that represents an intermediary decoded value that can be used by decoder 824 to determine, for example, a conductive array line (e.g., an X-line or a Y-line) that is to be selected to access a corresponding memory cell. Therefore, a predecoded signal can be transmitted to any number of additional decoders 824 (not shown), thereby reducing area that otherwise might be consumed by implementing circuits that provide the functionality of predecoder 820 for each decoder 824. Decoder 824 can be configured to use the intermediary decoded value to select a X-line for accessing a row of memory cells in an array, such as a two-terminal memory cells in a two-terminal cross-point memory array.

Decode unit 800 and any of its constituent elements can be formed in a base layer to be entirely under a single array, or can be distributed and disposed under two or more arrays fabricated over the same base layer, in any combination, according to various embodiments of the invention. In at least some embodiments, any of the predecoder 820 and decoder 824 can be formed in a potential region, such as a p-type material used to form NMOS devices. Further, any of predecoder 820 and decoder 824 can be formed predominately or entirely of homogeneous transistors, such as NMOS devices or PMOS devices. While decode unit 800 is discussed above in terms of X-lines, it can be configured to select Y-lines. In some embodiments the X-lines could be considered the word lines and the Y-lines could be considered the bit lines. In other embodiments the lines would be reversed with the Y-lines being the word lines. In yet other embodiments describing the X-lines and Y-lines as word lines and bit lines would not make sense.

FIG. 8B depicts a predecoder 840 including a predecoder logic 841 and a level shifter circuit 842, according to at least some embodiments of the invention. Predecode logic 841 can be configured to generate predecoded signals that are communicated via one or more paths 847. Collectively, for purposes of illustration, the address bits in path 847 are denoted as bus 947. In this example, predecode logic 841 can be configured to receive a portion of an address, such as address bits A0 and A1, and to generate a predecoded signal indicating whether A0 is either in one state (i.e., A0) or in another state (i.e., /A0, or not A0), and whether A1 is either in one state or another state. Level shifter circuit 842 is shown in this example to include two level shifters: a level shifter (“L/S (PV)”) 844 configured to shift between an intermediate voltage value, V0, (e.g., 0 volts) and a positive voltage value, +V, (e.g., +3V), and a level shifter (“L/S(NV)”) 846 configured to shift between an intermediate voltage value, V0, (e.g., 0 volts) and a negative voltage value, −V, (e.g., −3V). Level shifter circuit 842 can include switches 843, which can be configured to select any of the values of the positive voltage, intermediary voltage, and the negative voltage and to generate level-shifted voltages, such as +2V, +V, 0, −V, and −2V volts. Further, switches 843 can apply any of the level-shifted voltages to the gates and another terminal of NMOS devices 848a and 848b. Thus, level shifter circuit 842 can be configured to control NMOS device 848a to drive line 849 to either 0 or +V volts, and can also control NMOS device 848b to drive line 849 to either −V or 0 volts. In at least some examples, level shifter circuit 842 is configured to receive part of an address, such as address bits A0 and A1 via bus 947, and supply voltages, such as from V, 0, and +V volts to operate the NMOS devices 848a and 848b. In operation, level shifter circuit 842 can be configured to receive a part of an address, and to determine, based on the address part, whether to enable either of the NMOS devices 848a and 848b. When disabled, NMOS devices 848a and 848b are unselected and generate, for example, 0 volts. Level shifter circuit 842 also can be configured to receive control signals to determine the type of data operation that is pending for a memory cell, such as write operation, read operation, or the like. Once level shifter circuit 842 determines the data operation associated with the memory access, level shifter circuit 842 can control NMOS devices 848a and 848b and switches 843 to generate either −V or +V volts to be applied to line 849.

Thus, predecoder 820 can be configured to decode a portion of an address (e.g., a group of address bits) and to generate a predecoded signal that represents an intermediary decoded value that can be used by decoder 824 to determine, for example, an X-line that is to be selected to access a corresponding memory cell. Therefore, a predecoded signal can be transmitted to any number of decoders 824 (not shown), thereby reducing area that otherwise might be consumed by implementing circuits that provide the functionality of predecoder 820 for each decoder 824. Decoder 824 can be configured to use the intermediary decoded value to select the X-line for accessing a row of memory cells. Although not depicted an optional row selector electrically coupled with output of decoder 824 can be configured to select one of a group of rows that is determined by the decoder 824 to access a specific memory cell. In some cases, the row selector can be formed as an NMOS-based pass transistor.

FIG. 8C depicts a decoder 850 including a number of stages, according to at least some embodiments of the invention. In this example, decoder 850 can be configured as a tree decoder that is composed of NMOS devices having any number of stages. Namely, decoder 850 can include a first stage 852 and a second stage 854, with other stages not shown. First stage 852 and second stage 854 can be controlled by predecoded signals on path 847. Further, a data signal sent via 849 can be propagated through a tree structure of NMOS devices, as a function of the values of predecoded signals on path 847. Leakers 856 can be optional, and, if used, can ensure that the conductive array lines are not floating or in some unintended state. Although not depicted, decoder 850 can be implemented for Y-lines (e.g., bit lines) as well.

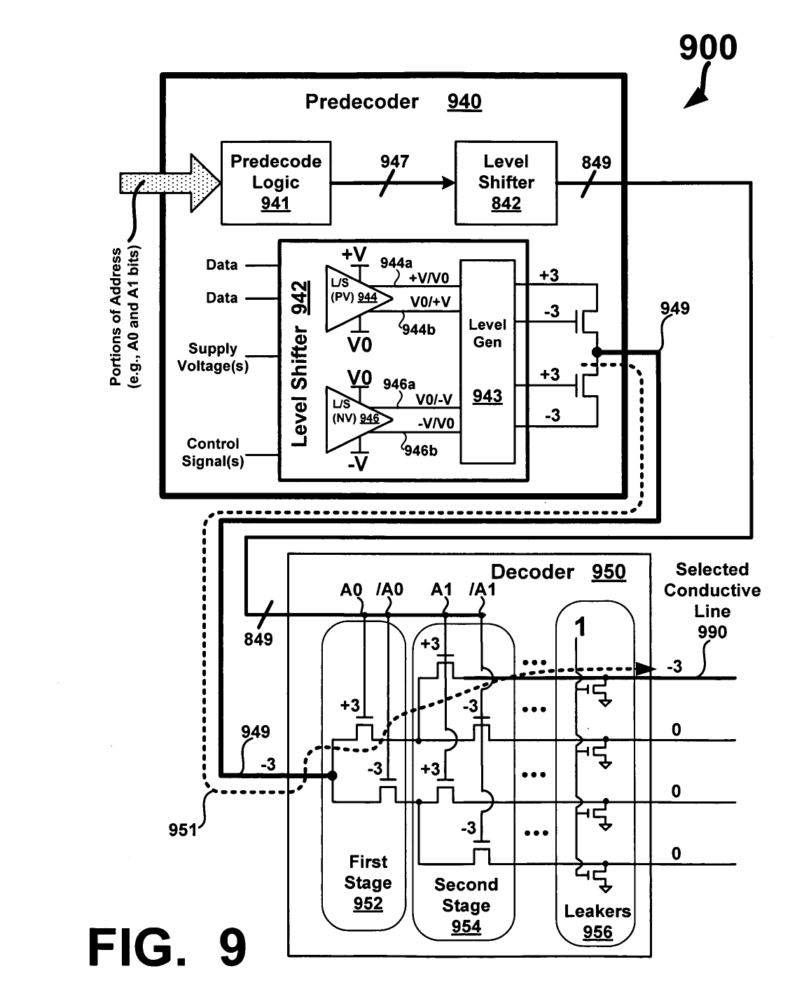

FIG. 9 depicts a decoder 900 including a predecoder 940 and a decoder 950, according to at least some embodiments of the invention. In this example, predecoder 940 includes predecode logic 941 and level shifters 842 and 942. Level shifter 942 includes level shifters 944 and 946, and a level generator (“level gen”) 943. Further, decoder 950 operates as a post-decoder, and includes a first stage 952, a second stage 954, and optional leakers 956. In this example, predecoder 940 is configured to generate a −3 volts at line 949, and predecode logic 941 is configured to transmit control signals to route the −3 volts via a path 951 from level shifter 942 to the selected conductive array line 990. Level shifter 842 is configured, based on signals on bus 947, to provide voltage signals operative to activate the appropriate NMOS devices in the first stage 952 and second stage 954 such that the appropriate level shifted voltage is applied to the selected conductive array line (e.g., conductive line 990).

The various embodiments of the invention can be implemented in numerous ways, including as a system, a process, an apparatus, or a series of program instructions on a computer readable medium such as a computer readable storage medium or a computer network where the program instructions are sent over optical or electronic communication links. In general, the steps of disclosed processes can be performed in an arbitrary order, unless otherwise provided in the claims.

The foregoing description, for purposes of explanation, uses specific nomenclature to provide a thorough understanding of the invention. However, it will be apparent to one skilled in the art that specific details are not required in order to practice the invention. In fact, this description should not be read to limit any feature or aspect of the present invention to any embodiment; rather features and aspects of one embodiment can readily be interchanged with other embodiments. Notably, not every benefit described herein need be realized by each embodiment of the present invention. Furthermore, any specific embodiment can provide one or more of the advantages discussed above. In the claims, elements and/or operations do not imply any particular order of operation, unless explicitly stated in the claims. It is intended that the following claims and their equivalents define the scope of the invention.

What is claimed is:

1. An integrated circuit, comprising:
a substrate;
at least one cross-point memory array formed above the substrate and having a perimeter defined by the dimensions of the at-least-one-cross-point-memory array, each cross-point-memory array including
a plurality of X-line conductive array lines having interdigitated X-line connection points, and
a plurality of Y-line conductive array lines having interdigitated Y-line connection points,
an X-line decoder fabricated on the substrate and configured to access the X-line conductive array lines using the X-line connection points; and
a Y-line decoder fabricated on the substrate and configured to access the Y-line conductive array lines using the Y-line connection points;
wherein the X-line decoder and the Y-line decoder are positioned substantially within the perimeter.

2. The integrated circuit of claim 1, wherein at least a portion of the Y-line connection points are not positioned directly above at least a portion of the Y-line decoder.

3. The integrated circuit of claim 2, further comprising an interface layer positioned between and in contact with the at-least-one-cross-point-memory array and the substrate, the interface layer including electrically-conductive structures configured to electrically couple the Y-line decoder to the Y-line connection points such that the electrically-conductive structures extend from a location directly below the at-least-a-portion-of-the-Y-line-connection points to directly above the at-least-a-portion-of-the-Y-line decoder.

4. The integrated circuit of claim 1, wherein the Y-line decoder includes a non-contiguous decoder portion that is formed separate from other portions of the Y-line decoder.

5. The integrated circuit of claim 1, wherein:
the at-least-one-cross-point-memory array includes at least a first cross-point memory array and a second cross-point memory array;
a first portion of the Y-line decoder is positioned underneath the first cross-point-memory array;
the first portion of the Y-line decoder is in communication with a second portion of the Y-line decoder positioned underneath the second cross-point memory array.

6. The integrated circuit of claim 5, wherein the first portion of the Y-line decoder is in communication with a third portion of the Y-line decoder positioned underneath the first cross-point memory array, the third portion configured to perform operations on the first cross-point memory array and the second portion configured to perform operations on the second cross-point memory array.

7. The integrated circuit of claim 6 wherein the first portion is a pre-decoder.

8. The integrated circuit of claim 1, further comprising:
one or more potential regions that constitute substantially all of the area within the perimeter, each potential region including a common semiconductor material for forming similar devices,
wherein only homogeneous transistors are formed in the one of the plurality of potential regions.

9. The integrated circuit of claim 8, wherein the homogenous transistors are all NMOS devices.

10. The integrated circuit of claim 8, wherein the homogenous transistors are all in a well isolated from other potential regions.

11. The integrated circuit of claim 10, wherein the well is biased negatively compared to the chip substrate.

12. The integrated circuit of claim 1, wherein the X-line decoder includes leaker circuits to prevent unselected x-lines from floating.

13. The integrated circuit of claim 1, wherein the X-line conductive array lines and the Y-line conductive array lines have a first minimum feature size is less than a second minimum feature size of the X-line decoder and the Y-line decoder.

14. An integrated circuit, comprising:
a substrate;
a plurality of memory layers formed above the substrate with each memory layer including at least one cross-point array, each cross-point array including
a plurality of interdigitated conductive array lines, the plurality of interdigitated conductive array lines including a plurality of X-line conductive array lines and a plurality of Y-line conductive array lines,
a plurality of non-volatile re-writable memory cells, each memory cell electrically in series with and positioned between a cross-point of only one of the plurality of X-line conductive array lines and only one of the plurality of Y-line conductive array lines;
a plurality of decoders fabricated on the substrate and configured to access the memory cells via the plurality of interdigitated conductive array lines, the plurality of decoders including a predecoder configured to generate predecoded signals and a postdecoder configured to receive the predecoded signals
an interface layer positioned between the plurality of memory layers and the substrate, the interface layer including electrically conductive structures configured to electrically couple the decoder portions to a least a subset of the interdigitated conductive array lines, and
wherein the postdecoders are positioned substantially underneath the plurality of memory layers.

15. The integrated circuit of claim 14, wherein the plurality of decoders further comprises only homogeneous transistors.

16. The integrated circuit of claim 14, wherein the plurality of decoder includes decoder portions that are non-contiguous with other decoder portions.

17. The integrated circuit of claim 14, wherein:
the at least one cross-point array includes at least a first cross-point array and a second cross-point array adjacent to the first cross-point array; and
the plurality of decoders includes a first postdecoder and a second postdecoder that are operative to receive an output from the predecoder,
wherein the predecoder and the first postdecoder is underneath the first cross-point array and the second postdecoder is underneath the second cross-point array.

18. The integrated circuit of claim 14, wherein the X-line conductive array lines and the Y-line conductive array lines have a first minimum feature size that is less than a second minimum feature size of the plurality of decoders.

19. The integrated circuit of claim 14, wherein the plurality of decoders include leaker circuits to prevent unselected conductive array lines from floating.

20. An integrated circuit comprising:
a substrate;
a cross-point memory array formed above the substrate, the cross-point memory array including
sets of conductive array lines arranged in different directions, and
a plurality of non-volatile re-writable memory cells, each memory cell electrically in series with and positioned between a cross-point of a pair of the conductive array lines; and
a memory access circuit electrically coupled with and configured to perform data operations on the cross-point memory array, the memory access circuit is fabricated on the substrate;
wherein the conductive array lines have a first minimum feature size that is less than a second minimum feature size of the memory access circuit.

21. An integrated circuit comprising:
a substrate;
a cross-point memory array formed above the substrate, the cross-point memory array including
sets of conductive array lines arranged in different directions, and
a plurality of non-volatile re-writable memory cells, each memory cell electrically in series with and positioned between a cross-point of a pair of the conductive array lines;
a memory access circuit electrically coupled with and configured to perform data operations on the cross-point memory array, the memory access circuit is fabricated on the substrate and substantially positioned within a perimeter defined by dimensions of the cross-point memory array; and
a cross-point memory array interface layer positioned between the cross-point memory array and the substrate, the interface layer including electrically conductive structures configured to electrically couple the memory access circuit with the conductive array lines in an interdigitated fashion.

22. The integrated circuit of claim 21, wherein each memory cell stores data as a plurality of conductivity profiles that can be non-destructively determined by applying a read voltage across the pair of conductive array lines.

23. The integrated circuit of claim 21, wherein the memory access circuit comprises only homogenous transistors.

24. The integrated circuit of claim 21, wherein the memory access circuit comprises at least a portion of a decoder circuit.

25. The integrated circuit of claim 21, wherein the memory access circuit comprises at least a portion of a sense amplifier.

26. The integrated circuit of claim 21, wherein the memory access circuit comprises at least a portion of leaker circuits to prevent unselected conductive array lines from floating.

27. The integrated circuit of claim 21, wherein the conductive array lines have a first minimum feature size that is less than a second minimum feature size of the memory access circuit.

28. The integrated circuit of claim 21, wherein each memory cell comprises a two terminal memory device.
